(19) United States
(12) Patent Application Publication
(10) Pub. No.: US 2006/0172522 A1
(43) Pub. Date: Aug. 3, 2006

(54) Method of fine patterning a metal layer

(75) Inventors: Seog-woo Hong, Yongin-si (KR); Byeoung-ju Ha, Seongnam-si (KR); Kyu-sik Kim, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD, Suwon-si (KR)

(21) Appl. No.: 11/298,481

(22) Filed: Dec. 12, 2005

(30) Foreign Application Priority Data
Jan. 31, 2005 (KR) 10-2005-0008544

(51) Int. Cl. H01L 21/44

(52) U.S. Cl. 438/597

(57) ABSTRACT

A method of fine patterning a metal layer which includes depositing a metal layer on a substrate; depositing, on the metal layer, a mask layer having a different degree of electrolytic dissociation than that of the metal layer; making a patterned substrate body; and dipping the substrate body into an electrolyte to thereby corrode the metal layer by an electric potential generated between the metal layer and the mask layer to obtain a desired pattern. The metal layer is a metal having a high degree of electrolytic dissociation for use as an anode, and the mask layer is a metal having a low degree of electrolytic dissociation for use as a cathode. Accordingly, the present invention can conduct fine patterning of a metal layer to a desired size.

This application claims benefit under 35 U.S.C. § 119 from Korean Patent Application No. 2005-08544, filed on Jan. 31, 2005, the entire content of which is incorporated herein by reference.

### BACKGROUND OF THE INVENTION

1. Field of the Invention

The present invention relates to a method of fine patterning a metal layer, and more particularly to a method of fine patterning a metal layer in which a metal layer is deposited on a substrate to form an interconnection for a MEMS element, or the like, and the metal layer is patterned into a desired shape.

In order to form an interconnection for a MEMS element or a semiconductor element, or the like, a metal layer to be patterned is generally formed on a substrate, and a mask layer is formed on the metal layer.

The mask layer is covered with a photoresist, and a pattern is formed by photolithography, thereby making a mask.

The mask on the metal layer is chemically etched using an etchant (hereinafter, called “wet etching”) for a certain amount of time to pattern the metal layer.

The mask is typically used to protect a certain surface from the etchant, and the mask is removed after wet etching.

However, this wet etching has a disadvantage of causing isotropic etching. Accordingly, a film to be etched is not useful due to the “undercut”. In a case where many layers of metals are etched using one mask, more serious undercut results, and it is not easy to obtain an exact pattern.

In addition, because the function of the mask is to protect a desired surface from the etchant, there is a limitation in that the mask should be selected from materials resistant to the etchant. In case of dry etching, there is a limitation in the process because an exclusive gas must be used according to a selected metal, whereby an expensive apparatus is required.

### SUMMARY OF THE INVENTION

The present invention has been developed in order to solve the above drawbacks and other problems associated with a conventional arrangement.

Thus, a first object of the present invention is to provide a method of fine patterning a metal layer which can mitigate a limitation in the use of an etchant by patterning a metal layer in accordance with the galvanic corrosion principal.

A second object of the present invention is to provide a method of fine patterning a metal layer which does not require the use of a strong acid etchant, thereby eliminating a safety problem.

The above objects of the present invention have been achieved by providing a method of fine patterning a metal layer according to a first aspect, which comprises depositing a metal layer on a substrate; depositing, on the metal layer, a mask layer having a different degree of electrolytic dissociation than that of the metal layer; patterning the substrate body, and specifically the mask layer; and dipping the substrate body into an electrolyte so as to corrode the metal layer by an electric potential generated between the metal layer and the mask layer to obtain a desired pattern.

The metal layer is preferably formed of a metal having a high degree of electrolytic dissociation for use as an anode, and the mask layer is a metal having a low degree of electrolytic dissociation for use as a cathode. Here, the metal layer is formed from at least one metal selected from the group consisting of Cr, Ti, Ni, Al, Zn and Mo, and the mask layer is formed from at least one metal selected from the group consisting of Au, Ag, Pt and Cu.

The corrosion rate can be adjusted by adjusting an exposed area of the metal layer relative to that of the mask layer.

The electrolyte is preferably an aqueous solution and further preferably a mild alkali solution. As an example, TMAH (tetra-methyl ammonium hydroxide) can be used as the electrolyte.

The metal layer below certain portions of the mask layer is undercut by the corrosion to set the mask layer apart from the substrate, thereby forming a floating structure.

The method of the present invention provides a novel method of patterning a metal layer.

In addition, the present invention has an advantage of making a more exact pattern of the metal layer.

Further, the present invention reduces the need for use of a corrosive liquid, and, furthermore, a strong acid liquid is not required, which eliminates a safety problem.

### BRIEF DESCRIPTION OF THE DRAWINGS

The above aspects and features of the present invention will be more apparent by describing certain embodiments of the present invention with reference to the accompanying drawings, in which:

FIG. 1A and FIG. 1B show a process for manufacturing a substrate body of the present invention;

FIG. 2 shows a process for forming a patterned metal layer by dipping the substrate body shown in FIG. 1A and FIG. 1B into an electrolyte;

FIG. 3 shows the metal layer of FIG. 2 patterned by galvanic corrosion;

FIG. 4 shows an example of making a floating structure comprising a portion of the mask layer by galvanic corrosion; and

FIGS. 5A, 5B, and 5C show the floating structure of FIG. 4.

### DETAILED DESCRIPTION OF THE PREFERRED EMBODIMENTS

Certain embodiments of the present invention will be described in greater detail with reference to the accompanying drawings. However, the present invention should not be construed as being limited thereto.

FIG. 1A and FIG. 1B show a process for manufacturing a substrate body of the present invention.

Referring to FIG. 1A, a metal layer 3 for patterning is formed on a substrate 1 such as, for example, a substrate made of Si. The metal layer 3 can be formed by a known deposition method. Then, a mask layer 5 is formed on the metal layer 3. The mask layer 5 is preferably a metal substance having a lower degree of electrolytic dissociation than that of the metal layer 3 so that the mask layer can be used as a cathode when it is dipped in an electrolyte 11. The mask layer 5 can also be deposited by a known deposition method, and patterning thereof can be performed by lift-off or wet etching. Referring to FIG. 1B, a mask is made by etching the mask layer 5 on the metal layer 3 and patterning it into a shape corresponding to an interconnection shape.

After the metal layer 3 and the mask layer 5 are laminated in turn as described above, the substrate body 7 with the mask layer thus patterned is dipped into an electrolyte 11 to pattern the metal layer 3 into a desired shape (for example, a wiring shape).

Next, a process for patterning the metal layer 3 by dipping the substrate body 7 into the electrolyte 11 is described in more detail.

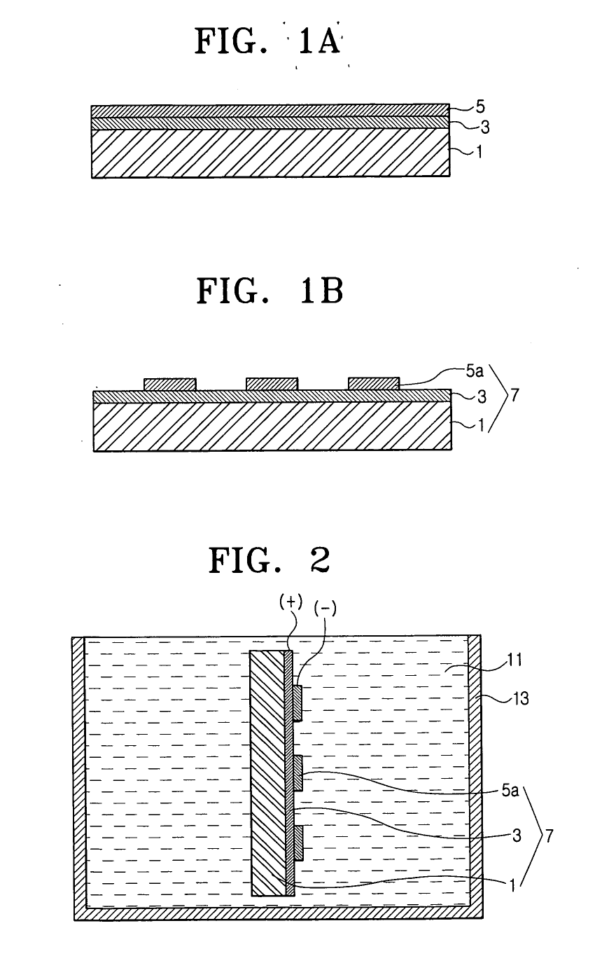

FIG. 2 shows a process for forming a patterned metal layer of the present invention.

Referring to FIG. 2, an electrolyte vessel 13 having an electrolyte 11 is prepared, where the electrolyte 11 is an aqueous solution, preferably a mild alkali solution. For example, TMAH (tetra-methyl ammonium hydroxide) can be used as the electrolyte. The temperature of the electrolyte is preferably in a range from room temperature to 80° C., where room temperature is from 15 to 25° C.

The substrate body 7 which has the metal layer 3 and the mask layer 5 to be patterned formed thereon is dipped into the electrolyte 11 in the electrolyte vessel 13. Here, the metal layer 3 is a metal having a high degree of electrolytic dissociation serving as an anode, and the mask layer 5 is a metal having a low degree of electrolytic dissociation serving as a cathode. Preferably, the metal layer 3 is made of a metal selected from the group consisting of Cr, Ti, Ni, Al, Zn and Mo, and the mask layer is made of a metal selected from the group consisting of Au, Ag, Pt and Cu. When different metals (i.e., the metal layer 3 and the mask layer 5) are dipped in the electrolyte 11 as described above, an electric potential is generated to cause movement of electrons therebetween. Therefore, the corrosion rate of the cathode mask layer 5 is decreased, and the corrosion rate of the anode metal layer 3 is increased. By this galvanic corrosion principal, the metal layer 3 is patterned into a desired shape.

This corrosion reaction proceeds favorably when the anode area is four times larger than the cathode area. Accordingly, the corrosion rate can be adjusted by adjusting the size of the anode area relative to the size of the cathode area.

FIG. 4 shows an example of making a floating structure comprising a portion of the mask layer by galvanic corrosion.

Referring to FIG. 4, when portions of the metal layer 53 are removed, mask layer 55 projecting from a portion of the metal layer 53 which has not been removed remains to form a floating structure 59 set at a certain vertical interval from the substrate 51. This floating structure may be used as a MEMS mirror, or used as a heater.

How to make the floating structure is now explained in detail.

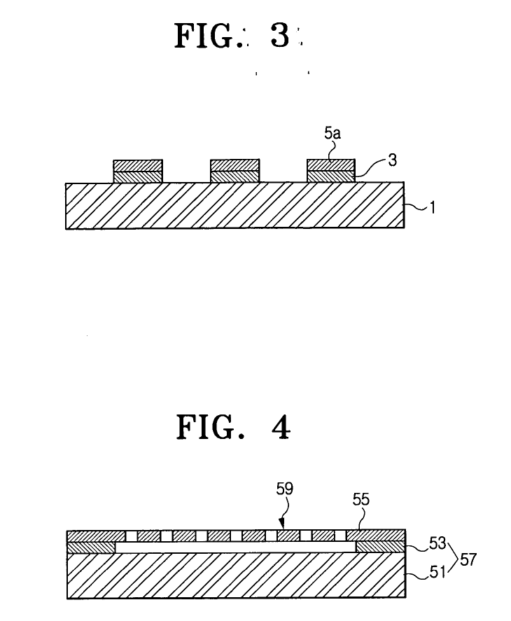

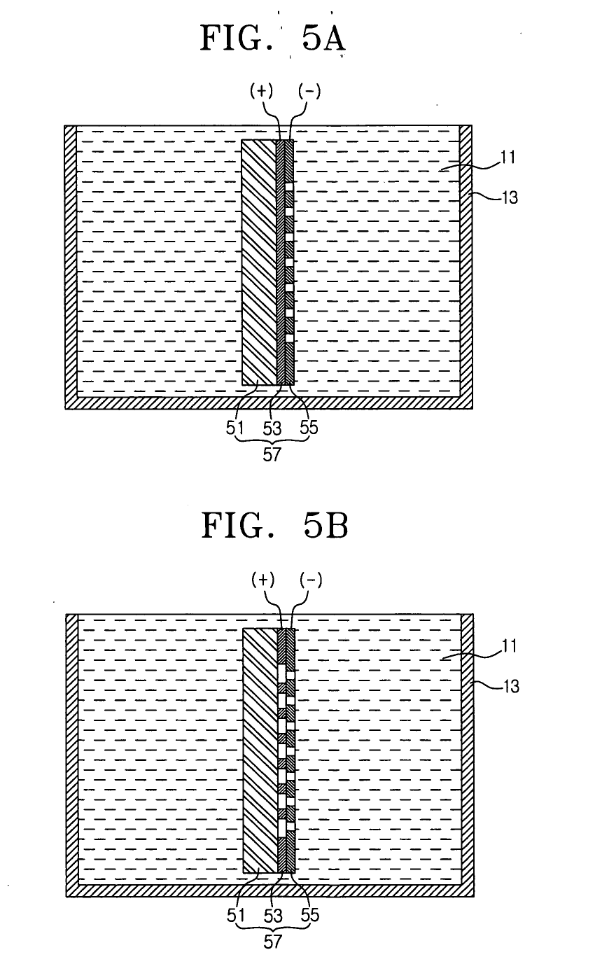

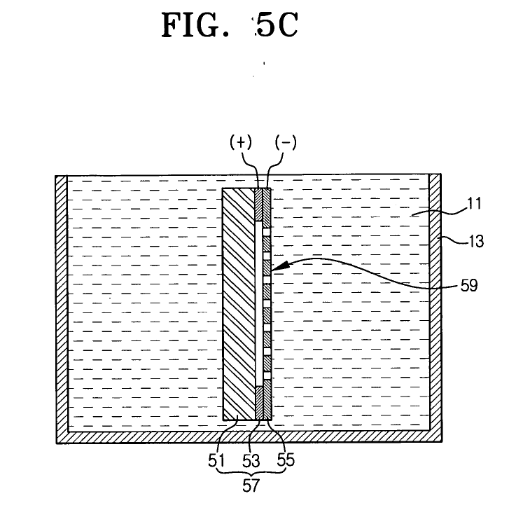

FIGS. 5A, 5B, and 5C show the floating structure of FIG. 4. With respect to the components which have like constructions and functions with those described in FIG. 3, further detailed descriptions will be omitted and identical reference numerals will be used.

Referring to FIG. 5A, when the metal layer 53 and the mask layer 55 are deposited on the substrate 51 in that order, the substrate body 57 having the patterned mask layer 55 is dipped into the electrolyte 11.

Referring to FIG. 5B, the metal layer 53 is corroded along the pattern of the mask layer 55 by the galvanic corrosion.

Referring to FIG. 5C, the galvanic corrosion continues and the metal layer 53 is undercut. Accordingly, only the mask layer 55 remains and thus the floating structure 59 can be made. The undercutting can be carried out by adjusting the sizes of the anode area and the cathode area or adjusting the corrosion time.

The foregoing embodiment and advantages are merely exemplary and are not to be construed as limiting the present invention. The present teaching can be readily applied to other types of apparatuses. Also, the description of the embodiments of the present invention is intended to be illustrative, and not to limit the scope of the claims, and many alternatives, modifications, and variations will be apparent to those skilled in the art.

What is claimed is:

1. A method of fine patterning a metal layer, which comprises
depositing a metal layer on a substrate;
depositing, on the metal layer, a mask layer having a different degree of electrolytic dissociation than that of the metal layer;
patterning the mask layer; and
dipping the substrate body into an electrolyte so as to corrode the metal layer by an electric potential generated between the metal layer and the mask layer to obtain a desired pattern.

2. The method of claim 1, wherein the metal layer is formed of a first metal serving as an anode, the mask layer is formed of a second metal serving as a cathode, and the first metal has a degree of electrolytic dissociation higher than that of the second metal.

3. The method of claim 1, which comprises adjusting a corrosion rate by adjusting an area of the metal layer relative to that of the mask layer.

4. The method of claim 1, wherein the electrolyte comprises an aqueous solution.

5. The method of claim 4, wherein the electrolyte comprises an alkali solution.

6. The method of claim 1 wherein the electrolyte comprises TMAH (tetra-methyl ammonium hydroxide).

7. The method of claim 1, which further comprises undercutting the metal layer below certain portions of the mask layer by the corrosion to set the mask layer apart from the substrate, thereby forming a floating structure.

8. The method of claim 2, wherein the metal layer is formed of at least one metal selected from the group consisting of Cr, Ti, Ni, Al, Zn and Mo.

9. The method of claim 2, wherein the mask layer is formed of at least one metal selected from the group consisting of Au, Ag, Pt and Cu.
